(19) United States
(12) Patent Application Publication
(10) Pub. No.: US 2024/0274571 A1
(43) Pub. Date: Aug. 15, 2024

(54) SEMICONDUCTOR SUBSTRATE ASSEMBLY AND MANUFACTURING METHOD THEREFOR

(71) Applicants: Tadatomo SUGA, Tokyo (JP); Kanji OTSUKA, Tokyo (JP); Institute for Advanced Micro-system Integration, Tokyo (JP)

(72) Inventors: Tadatomo SUGA, Tokyo (JP); Kanji OTSUKA, Tokyo (JP)

(21) Appl. No.: 18/565,741

(22) PCT Filed: May 30, 2022
(86) PCT No.: PCT/JP2022/021865

§ 371 Date: Nov. 30, 2023

(30) Foreign Application Priority Data
May 30, 2021 (JP) 2021-090724

(51) Int. Cl. H01L 23/00; H01L 21/02; H01L 23/50; H01L 23/66

(52) U.S. Cl. CPC H01L 24/83; H01L 21/022; H01L 23/50; H01L 23/66; H01L 24/97; H01L 2223/6616; H01L 2223/6638; H01L 2224/83001; H01L 2224/8322; H01L 2224/97; H01L 2924/1306; H01L 2924/1431

(57) ABSTRACT

According to an embodiment of the present disclosure, a bonding structure is provided, the bonding structure including: a first substrate including a first bonding surface including a first signal transmission metal region and a first ground metal region insulated from the first signal transmission metal region; and a second substrate bonded to the first substrate, the second substrate including a second bonding surface including a second signal transmission metal region and a second ground metal region insulated from the second signal transmission metal region, wherein the first signal transmission metal region and the second signal transmission metal region are bonded, and the first ground metal region and the second ground metal region are bonded.

### TECHNICAL FIELD

The present disclosure relates to a semiconductor substrate bonded body and a manufacturing method for the same.

### BACKGROUND ART

In recent years, with the development of cloud computing, information processing that handles big data has increased. In particular, in artificial intelligence (AI) processing, high-frequency and high-speed access to big data is required. In hardware, for example, structures such as a chiplet and a 3D mounting module have been evolved. A semiconductor electronic circuit has a multilayer lamination structure, and two layers or more layers are laminated. Here, electrical connections are formed between a wafer and a wafer, between a wafer and a chip, and between a chip and an interposer. Alternatively, the semiconductor electronic circuit has a three-dimensional structure, and wafers or chips are laminated. Due to this, for example, a memory module is formed, and an access bandwidth of a semiconductor memory can be increased. Alternatively, bonding between a wafer and a wafer is also employed in power semiconductors.

However, a manufacturing process including connection between a plurality of layers in these lamination structures, three-dimensional structures, and the like is complicated. Currently, its reliability is a very serious problem. Furthermore, demand for high-speed signals is high, but a structure that satisfies the bonding strength and high-speed signal transmission characteristics has not been proposed.

### SUMMARY OF INVENTION

In some embodiments of the present disclosure, a bonding structure or a bonded body including:
a first substrate including a first bonding surface including a first signal transmission metal region and a first ground metal region insulated from the first signal transmission metal region; and
a second substrate bonded to the first substrate, the second substrate including a second bonding surface including a second signal transmission metal region and a second ground metal region insulated from the second signal transmission metal region is provided.

In some embodiments, the first signal transmission metal region and the second signal transmission metal region are bonded.

In some embodiments, the first ground metal region and the second ground metal region are bonded.

According to the technology of the present disclosure, for example, dynamically strong bonding or highly reliable bonding can be achieved. Alternatively, for example, high-speed signal transmission characteristics in the electronic circuit can be maintained well. Furthermore, an electronic circuit, a module, or a system having such a three-dimensional structure can be constructed.

Further aspects and advantages of the present disclosure will become readily apparent to those skilled in the art from the following detailed description, in which only exemplary embodiments of the present disclosure are presented and described. As will be understood, the present disclosure is capable of other different embodiments, and its several details are capable of modification in various obvious respects without departing from the disclosure. Therefore, the drawings and description should be regarded as illustrative in nature and not as restrictive.

### BRIEF DESCRIPTION OF DRAWINGS

FIG. 1A is a cross-sectional view schematically illustrating a structure of a pair of substrates to be bonded according to an embodiment; and FIG. 1B is a cross-sectional view schematically illustrating a structure of a substrate bonded body manufactured by bonding of the pair of substrates.

FIG. 2A is a cross-sectional view schematically illustrating a structure of a pair of substrates to be bonded according to an embodiment; and FIG. 2B is a cross-sectional view schematically illustrating a structure of a substrate bonded body manufactured by bonding of the pair of substrates.

FIG. 3 is a cross-sectional view schematically illustrating a structure of a substrate bonded body including three substrates according to an embodiment.

FIG. 4 is a cross-sectional view schematically illustrating a structure of a substrate bonded body including three substrates according to an embodiment.

FIG. 5 is a perspective view schematically illustrating a structure of a substrate used for a substrate bonded body according to an embodiment.

FIG. 6 is a top view schematically illustrating a configuration of a bonding surface of a substrate according to an embodiment.

FIG. 7 is a top view schematically illustrating a configuration of a bonding surface of a substrate according to an embodiment.

FIG. 8 is a top view schematically illustrating a configuration of a bonding surface of a substrate according to an embodiment.

FIG. 9 is a top view schematically illustrating a configuration of a bonding surface of a substrate according to an embodiment.

FIG. 10 is a perspective view illustrating a structure of a substrate bonded body used for simulation.

FIG. 11 is a graph showing a pass characteristic and a reflection characteristic by simulation.

### DESCRIPTION OF EMBODIMENTS

### <1. Structure of Substrate and Bonded Body>

The term “substrate” used in the present description generally refers to a material of a flat plate of a semiconductor or an insulator. However, this term should not be construed as restrictive. The substrate should be construed broadly so as to refer to one or a plurality of materials or a structure on which a layer of one or a plurality of materials can be deposited. The substrate can include one or a plurality of layers of material deposited thereon. Although not restricted to them, the substrate can include, for example, a wafer or a chip including one or a plurality of layers of material. A dielectric layer, a metal layer, and the like are deposited thereon. The substrate may have a flat plate shape having a substantially constant thickness in a two-dimensional plane direction. However, the shape of the substrate is not limited to a flat plate. The substrate may have a three-dimensional shape.

The substrate may be a chip, a wafer, an element, a module, or the like. The substrate may be a printed circuit board (PCB), an interposer, an interposer substrate, or the like. The substrate may be a single side, double side, or multilayer PCB or interposer. The substrates to be bonded may be the same type of substrates or may be substrates belonging to different types or categories. For example, a chip and a chip, a wafer and a wafer, and a chip and a wafer may be bonded. For example, three or more substrates may be bonded. For example, one or a plurality of interposer substrates may be bonded between a plurality of semiconductor chips.

In some embodiments, the substrate has a bonding surface. The bonding surface may be defined as a surface or a surface region to be bonded to another substrate. In some embodiments, the bonding surface may have a metal region substantially made of a conductive material. In some embodiments, the bonding surface may have a non-metal region substantially made of a non-conductive material. The bonding surface may have a metal region and a non-metal region.

The “metal region” used in the present description generally refers to a surface region formed on a substrate surface or a bonding surface and substantially made of a conductive material. In some aspects, the metal region may be defined with respective to a dimension in a perpendicular direction with respective to the surface of the substrate.

In some embodiments, the surface (upper surface) of the metal region may be formed flat. The flat surface of the metal region may be substantially parallel to the bonding surface. In some embodiments, the surface of the metal region may be a curved surface or a surface having irregularities. The upper surface of the metal region may be configured to be bonded to another substrate. In some aspects, the upper surface of the metal region may be configured to protrude from the upper surface of the non-metal region provided on the same bonding surface. In some aspects, the upper surface of the metal region may have substantially the same height as the upper surface of the non-metal region provided at the same bonding surface.

The metal region may be connected to a through electrode (in the present description, it may be called a through-silicon via (TSV) regardless of whether or not the substrate material is mainly Si) partially or completely penetrating the inside of the substrate. The metal region may be connected to an extraction electrode disposed along the substrate surface or passing through the interior and leading to an end part.

The “metal” used in the present description generally refers to a conductive material unless otherwise stated. The “metal” may be substantially made of or include a metal material, a non-metal material, or a mixture thereof. The conductive material may be, for example, non-restrictively, a material that is used or can be used as a semiconductor wiring material. The metal material (hereinafter, may be called “metal”) may be selected from the group consisting of aluminum (Al), copper (Cu), cobalt (Co), ruthenium (Ru), silver (Ag), and gold (Au), or a group of some thereof. The metal material may be another metal. The metal material may be a mixture or alloy of a plurality of any of them. The conductive material may be a non-metal conductive material. The conductive material may be, for example, non-restrictively, made of carbon (C) or may include it. A carbon material includes, for example, non-restrictively, multilayered graphene (MLG) and carbon nanotube (CNT).

In some embodiments, the substrate may have a signal transmission metal region and a ground metal region on its bonding surface.

The term “signal transmission metal region” used in the present description refers to a metal region used for signal transmission in a bonded body. A plurality of signal transmission metal regions may be disposed on the bonding surface. In the bonded body, a signal is transmitted through the signal transmission metal region. In some embodiments, the bonded body may have a high-speed signal transmission structure in the GHz and THz bands and a function capable of coping with 10 W to 1000 W. The bonded body may be a connection structure used in an information processing device.

The signal transmission metal region may include at least one signal transmission metal region for transmitting an analog signal. The signal transmission metal region may include at least one signal transmission metal region for transmitting a digital signal. The signal transmission metal region may include at least one analog signal transmission metal region and at least one digital signal transmission metal region on the same bonding surface.

The term “ground metal region” used in the present description refers to a metal region connected to, for example, the ground and a power supply, and not intended for signal transmission in a bonded body. In some embodiments, the “ground metal region” may be defined as a metal region other than the signal transmission metal region. A plurality of ground metal regions may be disposed on the bonding surface. The ground metal region may be connected to the ground of the bonded body. The “ground metal region” may include a ground metal region in a narrow sense connected to the ground. In some embodiments, the “ground metal region” may include a power supply metal region connected to a power supply. The power supply provides power to the electronic element inside the bonded body or to which the bonded body is connected. In some embodiments, the ground metal region may be connected or configured to be connected to any of the ground and the power supply in the bonded body. In some embodiments, the ground metal region may be electrically connected or configured to be connected to the power supply. The power supply may be used for driving an electronic element that outputs or receives a signal transmitted through the bonding structure. The power supply may be electrically connected to the electronic element. The ground metal region may be connected to any polarity of the power supply. The power supply may include a plurality of power supplies. The plurality of power supplies may be connected to or configured to be connected to the plurality of ground metal regions.

In some embodiments, the ground metal region may have a function of thermal conduction. Such ground metal region may be called a heat dissipation metal region. The heat dissipation metal region may be connected to a thermal via penetrating the substrate. Due to this, for example, heat generated in a device or a substrate structure can be conducted to the outside or cooled. The thermal vias may be connected to each other across a plurality of layers or substrates and may connect the heat dissipation metal regions of the plurality of layers or substrates. The heat dissipation metal region may be connected to a heat dissipation plate via the thermal via or the like. The heat dissipation plate may be disposed in a final layer (uppermost layer or lowermost layer) of the substrate structure, for example. In some embodiments, the heat dissipation metal region may be disposed in connection with a lamination structure in a power device or inside thereof. The power device may include the heat dissipation metal region.

The ratio (a/A) of the total area (a) of the signal transmission metal region and the ground metal region to the area (A) of the bonding surface on which they are disposed may be equal to or greater than any value of 10, 15, 20, 25, 30, 35, 40, 45, 50, 55, 60, 65, 70, 75, 80, 85, 90, 95%, or may be larger than that. In some embodiments, this ratio (a/A) may be equal to or greater than 25%. In some embodiments, this ratio (a/A) may be equal to or greater than 30%. In some embodiments, this ratio (a/A) may be equal to or greater than 60%. This ratio may be different for each substrate or for each substrate surface in one bonded body.

In some embodiments, on the same bonding surface, the area of the ground metal region may be larger than the area of the first or second signal transmission metal region.

By bonding the ground metal region having a relatively large area, it is possible to sufficiently increase the bonding strength of the two bonded substrates. For example, it is possible to obtain sufficient strength against thermal stress or application of a force from the outside (such as impact in falling).

The ground metal region and the signal transmission metal region may be insulated from each other. The ground metal region and the signal transmission metal region may be insulated in the bonding surface. The ground metal region and the signal transmission metal region may be always insulated from each other over the entire bonded body. The ground metal region and the signal transmission metal region may be insulated by an insulating material disposed between them. The insulating material may form an insulating surface on the bonding surface. The insulating surface may be configured to be in contact with or bonded to another substrate. The ground metal region and the signal transmission metal region may be disposed contactlessly or so as not to be in contact with each other in the bonding surface. The ground metal region and the signal transmission metal region may be insulated from each other by gas or substantial vacuum.

In some aspects, the ground metal region and the signal transmission metal region may be separated from each other in the bonding surface or in an in-plane direction of the bonding surface. The separation distance in the in-plane direction of the bonding surface may be equal to or greater than any value of 0.05 μm, 0.06 μm, 0.07μm, 0.08 μm, 0.09 μm, 0.1 μm, 0.2 μm, 0.3 μm, 0.4 μm, 0.5 μm, 0.6 μm, 0.7 μm, 0.8 μm, 0.9 μm, and 1 μm, or may be larger than that.

The ground metal region may be disposed so as to surround the signal transmission metal region in the corresponding bonding surface.

In some embodiments, the ground metal region may have a metal material formed or disposed substantially gaplessly or planarly over the entire region. In other words, the metal region of the ground metal region may be formed substantially gaplessly over the entire region.

In some embodiments, the metal material of the ground metal region may be formed in a part of the region in terms of area. In some aspects, the ground metal region may have a metal material non-occupancy part (also called a void or a non-metal material part) where no metal material is disposed. The metal material or the metal material non-occupancy part may be periodically disposed or formed in the entirety or a part of the ground metal region. For example, the metal material or the metal material non-occupancy part may be disposed or formed in a mesh shape in the entirety or a part of the ground metal region.

The area ratio occupied by the metal material non-occupancy part in the ground metal region may be equal to or greater than any value of 5%, 10%, 20%, 30%, 40%, 50%, and 60%, or may be larger than that.

The area ratio occupied by the metal material non-occupancy part in the ground metal region may be equal to or less than any value of 90%, 80%, 70%, 60%, 50%, 40%, 30%, 20%, and 10%, or may be smaller than that.

The substrate bonded body or the bonding structure of the present disclosure may be connected to various electronic circuits or the like, may be configured to be connected thereto, or may include them therein. The electronic circuit may be an optoelectronic circuit (in the present description, an “optoelectronic circuit” or the like may be simply also called an “electronic circuit” or the like). The electronic circuit includes, for example, non-restrictively, an electronic element, an electronic circuit module, an electronic product, and an electronic system. The electronic element includes, for example, non-restrictively, a transistor (MOS, CMOS, FET, CMOS, or the like), an operational amplifier, a diode, a resistor, an inductor, a capacitor, a photocoupler, a transformer, and a relay. The electronic circuit may include one or both of a digital circuit and an analog circuit.

The electronic circuit may be a digital circuit or an element, or may be a logic circuit. The electronic circuit may be a logic circuit or an integrated circuit (IC) (e.g., SSI, MSI, LSI, VLSI, ULSI, WSI, SoC, CCD, CMOS image sensor, or the like). The electronic circuit may be a central processing unit (CPU), a graphic processing unit (GPU), or the like. The electronic circuit includes, for example, non-restrictively, a gate circuit such as an AND gate, an OR gate, a NOT gate, a NAND gate, a NOR gate, and an ExOR gate; a logical functional block such as a flip-flop, a counter, a register, a shift register, a latch, an encoder/decoder, a multiplexer/demultiplexer, an adder, and a comparator; a circuit having an amplification function such as a buffer and an inverter; and a switch, a multiplexer, an oscillator, or a phase-locked loop (PLL). The electronic circuit may be an analog circuit or an element. The electronic circuit includes, for example, non-restrictively, an amplifier circuit, an oscillation circuit, a filter circuit, an arithmetic circuit, impedance matching, a modulation circuit, a power supply circuit, and a high frequency circuit.

### First Embodiment

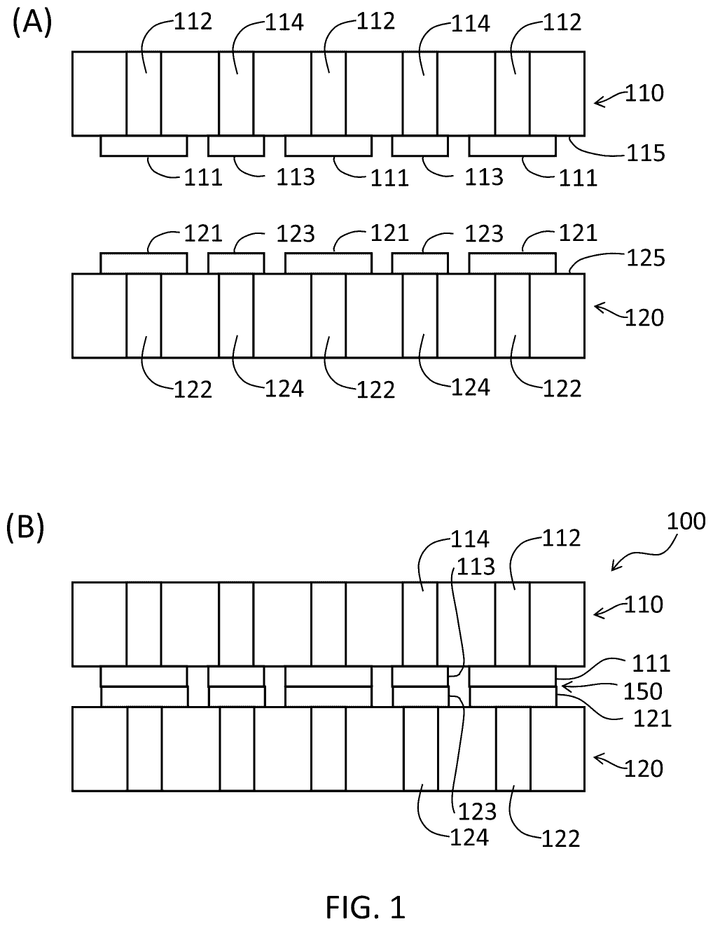

One embodiment will be described with reference to FIG. 1. FIG. 1A schematically illustrates two substrates 110 and 120 to be bonded.

The substrate 110 includes a ground metal region 111 and a signal transmission metal region 113 formed on a bonding surface of a substrate body formed of a semiconductor or an insulator. The substrate 110 is further formed such that a through electrode 112 connected to the ground metal region 111 and a through electrode 114 connected to the signal transmission metal region 113 penetrate the substrate 110. The ground metal region 111 and the signal transmission metal region 113 are formed to protrude from a surface (insulating surface) 115 on the bonding surface of the substrate body 110. In FIG. 1A, the ground metal region 111 and the signal transmission metal region 113 are formed such that surfaces thereof have substantially the same height with respect to the insulating surface 115 or the substrate body 110.

The substrate 120 has the same configuration as the substrate 110. The substrate 120 includes a ground metal region 121 and a signal transmission metal region 123 formed on a bonding surface of a substrate body formed of a semiconductor or an insulator. The substrate 120 is further formed such that a through electrode 122 connected to the ground metal region 121 and a through electrode 124 connected to the signal transmission metal region 123 penetrate the substrate 120. The ground metal region 121 and the signal transmission metal region 123 are formed to protrude from a surface (insulating surface) 125 on the bonding surface of the substrate body 120. In FIG. 1A, the ground metal region 121 and the signal transmission metal region 123 are formed such that surfaces thereof have substantially the same height with respect to the insulating surface 125 or the substrate body 120.

As illustrated in FIG. 1B, the ground metal region 111 of the substrate 110 and the ground metal region 121 of the substrate 120 are bonded, and the signal transmission metal region 113 of the substrate 110 and the signal transmission metal region 123 of the substrate 120 are bonded. By this bonding, a bonding interface 150 is formed between the metal regions. Due to this, the ground metal region 111 and the through electrode 112 of the substrate 110 and the ground metal region 121 and the through electrode 122 of the substrate 120 are electrically connected. Due to this, the substrate 110 and the substrate 120 are bonded, and a substrate bonded body 100 is manufactured. Here, the insulating surface 115 of the substrate 110 and the insulating surface 125 of the substrate 120 are not in contact with each other or are not bonded to each other. The insulating surface 115 of the substrate 110 and the insulating surface 125 of the substrate 120 need not be partially or entirely in contact with each other or need not be bonded to each other.

Not limited to the present embodiment, a bonding interface having high strength can be formed by bonding the ground metal region.

### Second Embodiment

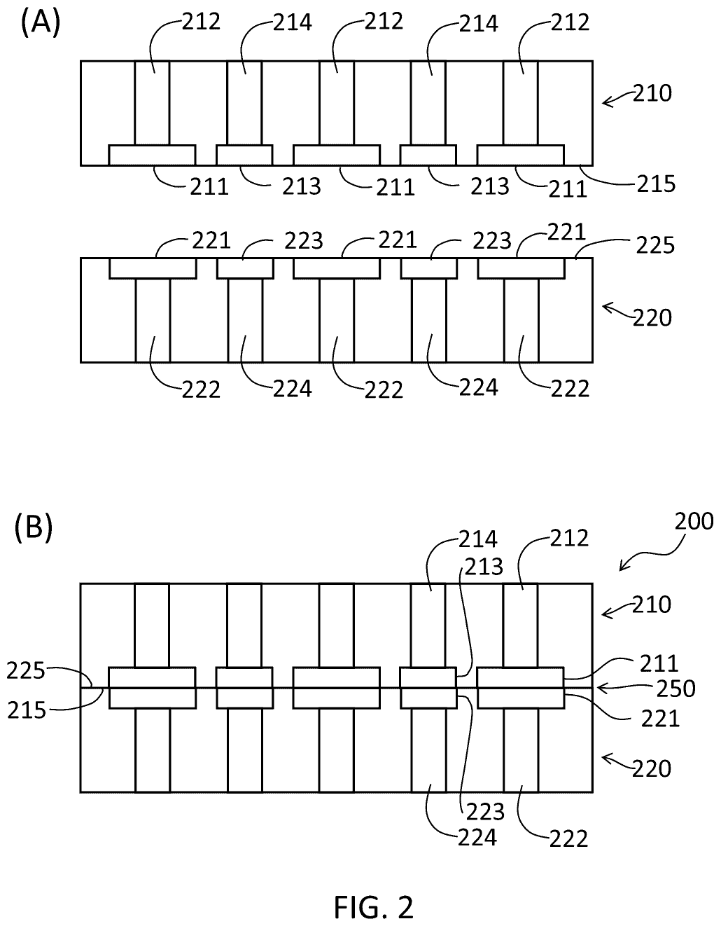

In some embodiments, the insulating surface of the substrate may be configured to be in contact before, during, or after a bonding process, or may be bonded. One embodiment will be described with reference to FIG. 2. FIG. 2A schematically illustrates two substrates 210 and 220 to be bonded.

The substrate 210 includes a ground metal region 211 and a signal transmission metal region 213 formed on a bonding surface of a substrate body formed of a semiconductor or an insulator. The substrate 210 of FIG. 2 is further formed such that a through electrode 212 connected to the ground metal region 211 and a through electrode 214 connected to the signal transmission metal region 213 penetrate the substrate 210. The ground metal region 211 and the signal transmission metal region 213 are formed so as to be substantially flush with a surface (insulating surface) 215 on the bonding surface of a substrate body 210. In other words, the surfaces of the ground metal region 211, the signal transmission metal region 213, and the insulating surface 215 have substantially the identical height in the substrate 210. The substrate 220 also has the same configuration as the substrate 210.

As illustrated in FIG. 2B, the ground metal region 211 of the substrate 210 and the ground metal region 221 of the substrate 220 are bonded, the signal transmission metal region 213 of the substrate 210 and the signal transmission metal region 223 of the substrate 220 are bonded, and the insulating surface 215 of the substrate 210 and the insulating surface 225 of the substrate 220 are bonded. By this bonding, a bonding interface 250 is formed between the metal regions. Due to this, the ground metal region 211 and the through electrode 212 of the substrate 210 and the ground metal region 221 and the through electrode 222 of the substrate 220 are electrically connected. Due to this, the substrate 210 and the substrate 220 are bonded, and a substrate bonded body 200 is manufactured. Here, the insulating surface 215 of the substrate 210 and the insulating surface 225 of the substrate 220 are in contact with or bonded to each other. The insulating surface 215 of the substrate 210 and the insulating surface 225 of the substrate 220 are partially or entirely in contact with or bonded to each other.

Not limited to the present embodiment, a bonding interface having a higher strength can be formed by bonding the insulating surfaces.

In some embodiments, bonding of the insulating surface can occur even when the metal region protrudes with respect to the insulating surface as in FIG. 1. For example, the metal region can first come into contact with another substrate, and then or simultaneously, the insulating surface can come into contact with another substrate due to elastic or plastic deformation of the substrate. When the surface of the insulating surface has a high binding force (e.g., activated), such a phenomenon is likely to occur.

In some embodiments, the metal region may be formed in a concave shape with respect to the insulating surface (not illustrated). In other words, the metal region may be formed low with respect to the insulating surface. In this case, the insulating surface comes into contact with another substrate. However, the metal region may then come into contact with another substrate by expansion due to heating. Alternatively, atoms in the metal region may be diffused by heating and reach another substrate.

### Third Embodiment: Multilayer Structure 1

In some embodiments, equal to or greater than three substrates may be bonded.

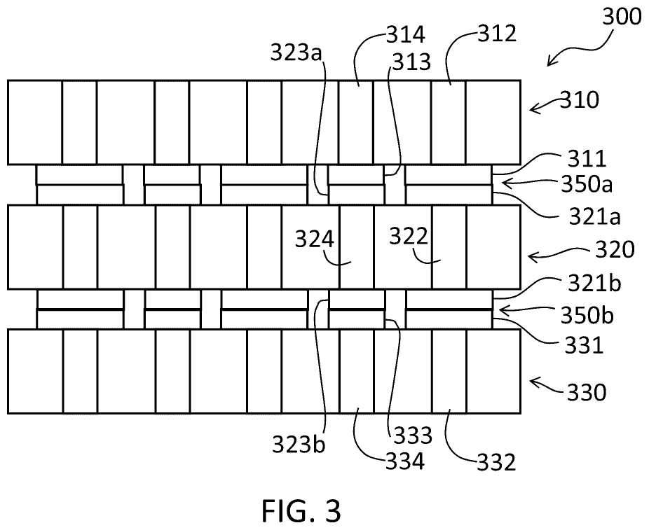

One embodiment will be described with reference to FIG. 3. A substrate bonded body 300 illustrated in FIG. 3 includes an upper substrate 310, a lower substrate 330, and an intermediate substrate 320 held between them. Here, in each substrate, as illustrated in the first embodiment, the metal region protrudes from the insulating surface on each bonding surface. The intermediate substrate 320 may be, for example, non-restrictively, an interposer substrate.

A ground metal region 321a and a signal transmission metal region 323a are disposed on the upper surface of the intermediate substrate 320, and bonded to a ground substrate region 311 and a signal transmission metal region 313, respectively, of the upper substrate 310. A ground metal region 321b and a signal transmission metal region 323b are disposed on the lower surface of the intermediate substrate 320, and bonded to a ground substrate region 331 and a signal transmission metal region 333, respectively, of the lower substrate 330. By this bonding, bonding interfaces 350a and 350b are formed between the respective metal regions. Due to this, a ground metal region 311 and a through electrode 312 of the upper substrate 310, the ground metal region 321a, a through electrode 322, and the ground metal region 321b of the intermediate substrate 320, and the ground metal region 331 and a through electrode 332 of the lower substrate 330 are electrically connected. Furthermore, the signal transmission metal region 313 and a through electrode 314 of the upper substrate 310, the signal transmission metal region 323a, a through electrode 324, and the signal transmission metal region 323b of the intermediate substrate 320, and the signal transmission metal region 333 and a through electrode 334 of the lower substrate 330 are electrically connected. The upper substrate 310, the intermediate substrate 320, and the lower substrate 330 are bonded to form the substrate bonded body 300.

### Fourth Embodiment: Multilayer Structure 2

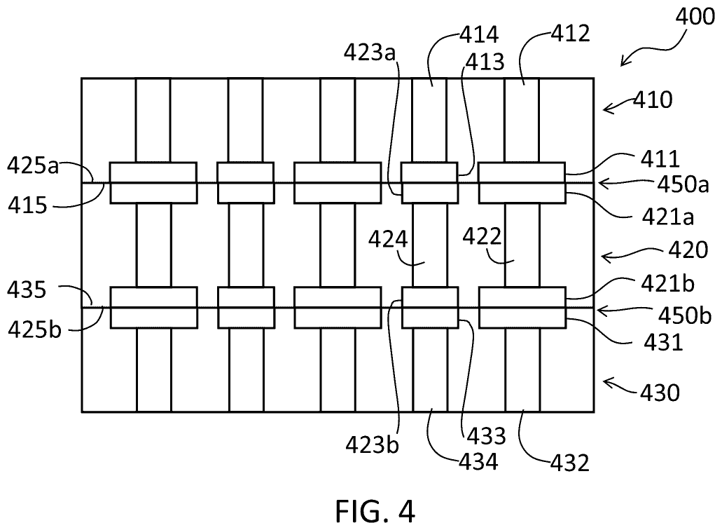

One embodiment will be described with reference to FIG. 4. A substrate bonded body 400 illustrated in FIG. 4 includes an upper substrate 410, a lower substrate 430, and an intermediate substrate 420 held between them. Here, in each substrate, as illustrated in the second embodiment, the metal region is formed to be substantially flush with the insulating surface on each bonding surface. Similarly to the third embodiment, the intermediate substrate 420 may be, for example, non-restrictively, an interposer substrate.

A ground metal region 421a, a signal transmission metal region 423a, and an insulating surface 425a are disposed on the upper surface of the intermediate substrate 420, and bonded to a ground substrate region 411, a signal transmission metal region 413, and an insulating surface 415, respectively, of the upper substrate 410. A ground metal region 421b, a signal transmission metal region 423b, and an insulating surface 425b are disposed on the lower surface of the intermediate substrate 420, and bonded to a ground substrate region 431, a signal transmission metal region 433, and an insulating surface 435, respectively, of the lower substrate 430. By this bonding, bonding interfaces 450a and 450b are formed between the respective metal regions. Due to this, a ground metal region 411 and a through electrode 412 of the upper substrate 410, the ground metal region 421a, a through electrode 422, and the ground metal region 421b of the intermediate substrate 420, and the ground metal region 431 and a through electrode 432 of the lower substrate 430 are electrically connected. Furthermore, the signal transmission metal region 413 and a through electrode 414 of the upper substrate 410, the signal transmission metal region 423a, a through electrode 424, and the signal transmission metal region 423b of the intermediate substrate 420, and the signal transmission metal region 433 and a through electrode 434 of the lower substrate 430 are electrically connected. Furthermore, the insulating surface is bonded to another insulating surface.

The upper substrate 410, the intermediate substrate 420, and the lower substrate 430 are bonded to form the substrate bonded body 400.

### Example 1: Structure of Substrate

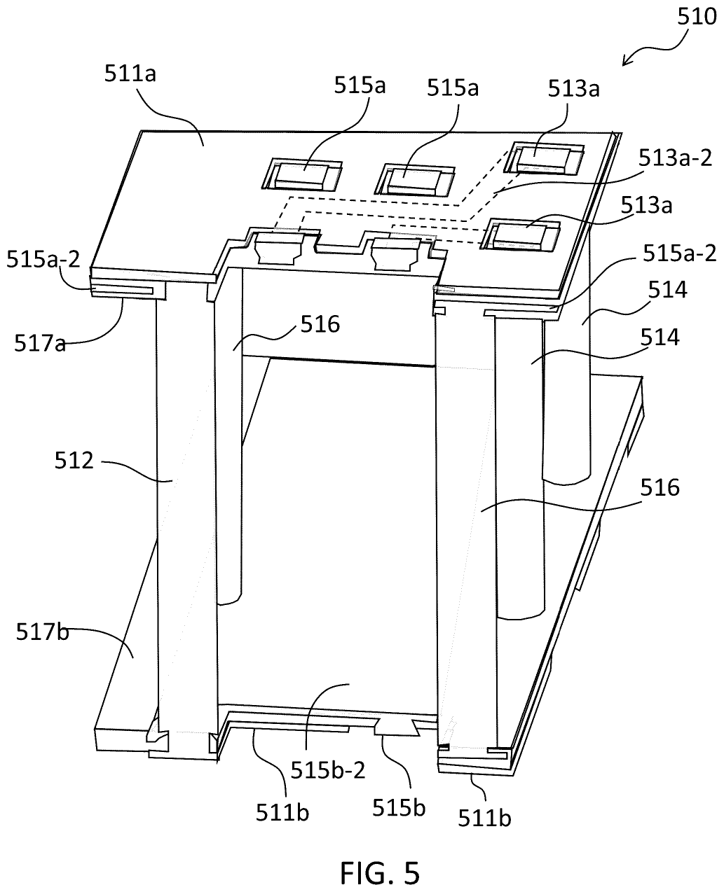

FIG. 5 illustrates, as a non-restrictive example, the structure of a substrate 510 that can be used as an interposer. FIG. 5 is a perspective view of the substrate 510, and a part of an insulator or a semiconductor in the center part thereof is omitted for the purpose of illustrating an internal structure.

The substrate 510 illustrated in FIG. 5 includes a ground metal region 511a, a signal transmission metal region 513a, and a power supply metal region 515a on the upper surface thereof, and is configured to be bonded to a corresponding region of the substrate to be bonded from the upper surface. Furthermore, a power plane 515a-2 is disposed in the second layer from the top, and connected to the power supply metal region 515a on the upper surface. Wiring 513a-2 connecting the plurality of the signal transmission metal regions 513a is disposed on the second layer from the top. They are insulated from each other by an organic insulator 517a. The ground metal region 511a is connected to a corresponding through electrode 512. The signal transmission metal region 513a is connected to a corresponding through electrode 514. The power supply metal region 515a is connected to a power plane 515a-2 and a corresponding through electrode 516.

The substrate 510 illustrated in FIG. 5 further includes a ground metal region 511b, a signal transmission metal region 513b (not illustrated), and a power supply metal region 515b on the lower surface thereof, and is configured to be bonded to a corresponding region of the substrate bonded from the lower surface. A power plane 515b-2 is disposed in the second layer from the bottom and connected to the power supply metal region 515b on the lower surface. They are insulated from each other by an organic insulator 517b. The ground metal region 511b is connected to the corresponding through electrode 512. The signal transmission metal region 513b (not illustrated) is connected to the corresponding through electrode 514. The power supply metal region 515b is connected to the corresponding through electrode 516.

The bonding surface may include a digital signal transmission region and an analog signal transmission region, or may include one of them.

### Example 3: Configuration 1 of Bonding Surface

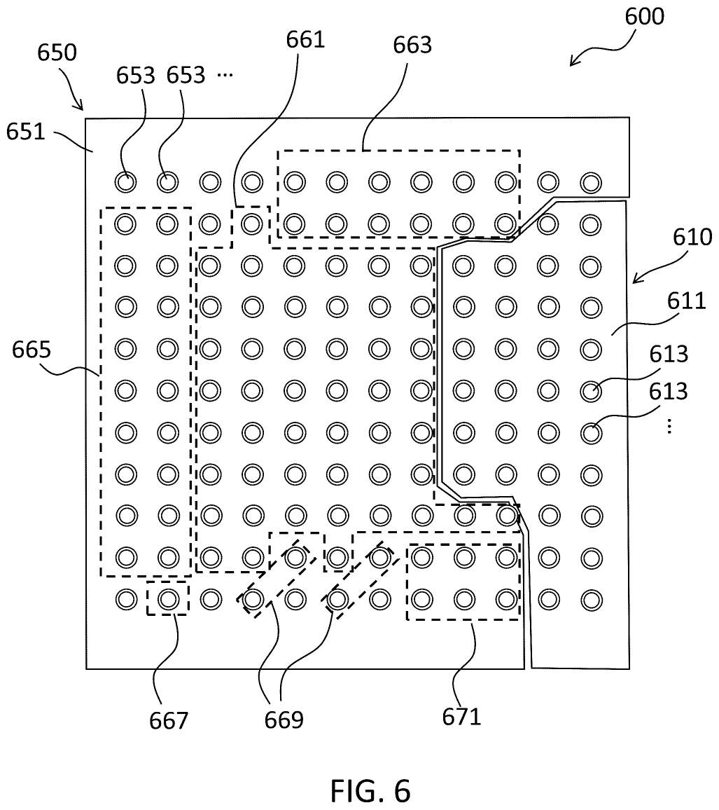

FIG. 6 illustrates the configuration of a bonding surface 600 including an analog signal transmission region 610 and a digital signal transmission region 650, as an example. FIG. 6 may be used, for example, non-restrictively, in any of an interposer and a PCB.

As illustrated in FIG. 6, the bonding surface 600 includes the analog signal region 610 and the digital signal region 650.

The analog signal region 610 includes an analog ground metal region 611 and an analog signal transmission metal region 613. A plurality of the analog signal transmission metal regions (or pads) 613 are disposed. The analog ground metal region 611 is disposed to be separated from and surround the analog signal transmission metal regions 613. The analog ground metal region 611 is connected to the ground (not illustrated). The analog signal transmission region 613 may be connected to or configured to be connected to an analog element. The analog signal transmission region 613 may correspond to various pins, and they include, for example, non-restrictively, the following:
a gate voltage (LNA_VDD), a ground (LNA_GND), an IN (LNA_IN), and a NIN (LNA_NIN) of a low noise amplifier (LNA);
a gate voltage (RI_VDD) and a ground (RI_GND) of a ring indicator (RI);
a gate voltage (TX_VDD), a ground (TX_GND), a differential pair of outputs OUT (TX_OUT), and a NOUT (TX_NOUT) of a transmission circuit (TX);
a Vdd (SW_VDD), a ground (SW_GND), and a differential pair of control (SW_CTL, NSW_CTL) of a switch (SW);
a test refresh (RF) signal (RF_TST);
a test ground (TEST_GND); and
a clock signal (TCLK_IN). The types of the analog signal transmission regions 613 illustrated in FIG. 6 and above are exemplarily illustrated, and these groups should not be construed restrictively.

The digital signal region 650 includes a digital ground metal region 651 and a digital signal transmission metal region 653. A plurality of the digital signal transmission metal regions (or pads) 653 are disposed. The digital ground metal region 651 is disposed to be separated from and surround the digital signal transmission metal regions 653. The digital ground metal region 651 is connected to the ground (not illustrated). A digital signal transmission region 653 may be connected to or configured to be connected to a digital element. A digital signal transmission region 613 may correspond to various pins. The digital signal transmission regions 613 are classified as follows according to the type of the signal to be transmitted. However, they include, for example, non-restrictively, the following:
a digital device (D) signal transmission region 661: a digital device gate voltage (D_VDD) and a ground (D_GND);
a control signal transmission region 663: (REQ (Request to Send), AQ (Acquire to Send), ENABLE (Enable for signal));
a high-speed bus signal transmission region 665: (Q/NQ (Output Signal/Negative output signal), D/ND (Input Signal/Negative input signal));
a signal transmission region 667 to an adjacent ball lid array;
a clock signal transmission region 669 (a data clock (DCLK), a timing circuit (TADJ), TX_VALID (Transmit Signal Valid), DPH (Data Phase timing), and the like)); and
a serial communication signal transmission region 671 (TXD/NTXD). However, the grouping and types of digital signal transmission regions 652 illustrated in FIG. 6 are exemplarily illustrated, and these groups should not be construed restrictively.

### Example 4: Configuration 2 of Bonding Surface

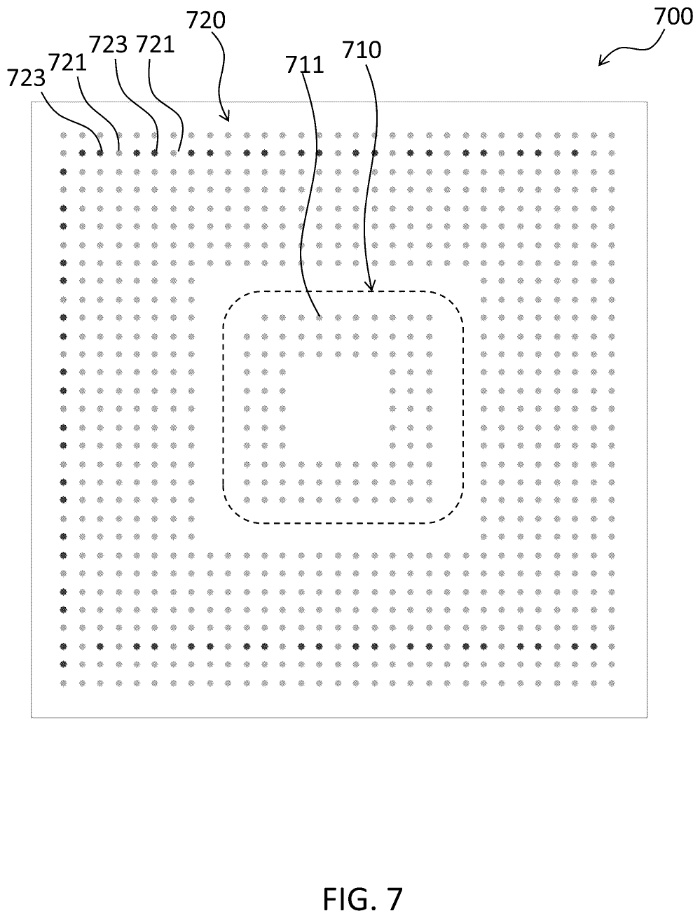

FIG. 7 illustrates the configuration of a bonding surface 700 including a ground metal region 710 and a signal transmission metal region 720 according to an example. FIG. 7 may be used, for example, non-restrictively, in any of an interposer and a PCB, and may be used on one side of a single end pad, for example.

The ground metal region 710 illustrated in FIG. 7 is defined at the center part of the bonding surface 700. A substantial metal part 711 of the ground metal region 710 is not formed singly, continuously, or gaplessly, but is individually formed as a pin 711. The pin 711 of the ground metal region 710 is connected or configured to be connected to the power supply or the ground.

The signal transmission metal region 720 illustrated in FIG. 7 is defined around and surrounding the ground metal region 710. A substantial metal part of the signal transmission metal region 720 is formed in a pin shape. The pin of the ground metal region 710 includes a metal region 721 for a signal and a metal region 723 for the ground. They are connected or configured to be connected to the gate voltage (VDD) or the ground (GND), respectively, of the device.

### Example 5: Configuration 4 of Bonding Surface

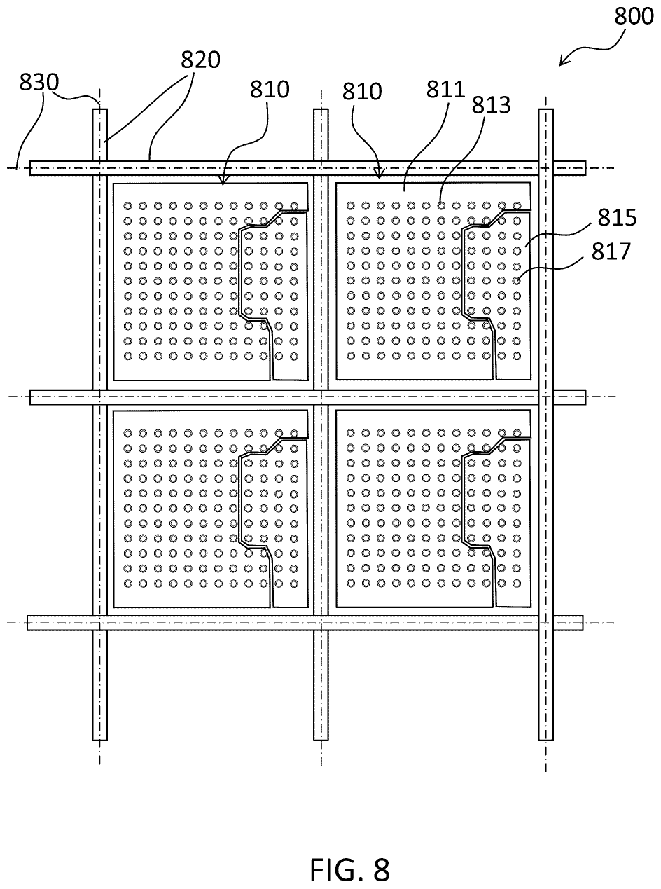

FIG. 8 illustrates a bonding surface 800 according to an example. The bonding surface 800 includes a plurality of chip regions 810. Each of the chip regions 810 includes a ground metal region 811 and a transmission metal region 813. A wafer including the bonding surface 800 is cut by dicing along a boundary line 830 defined in a grid shape on the bonding surface 800 at the boundary of the chip regions. The boundary line 830 indicated by a dashed line in FIG. 8 is geometrically defined on the wafer and need not necessarily be physically prepared on the surface of the wafer. The bonding surface 800 illustrated in FIG. 8 includes a cut metal region 820 including the boundary line 830. Therefore, the wafer is cut in this cut metal region 820 and divided into a plurality of chip regions 810. The cut metal region 820 may be connected or configured to be connected to the ground, or need not be connected to the ground.

### Example 6: Configuration 5 of Bonding Surface

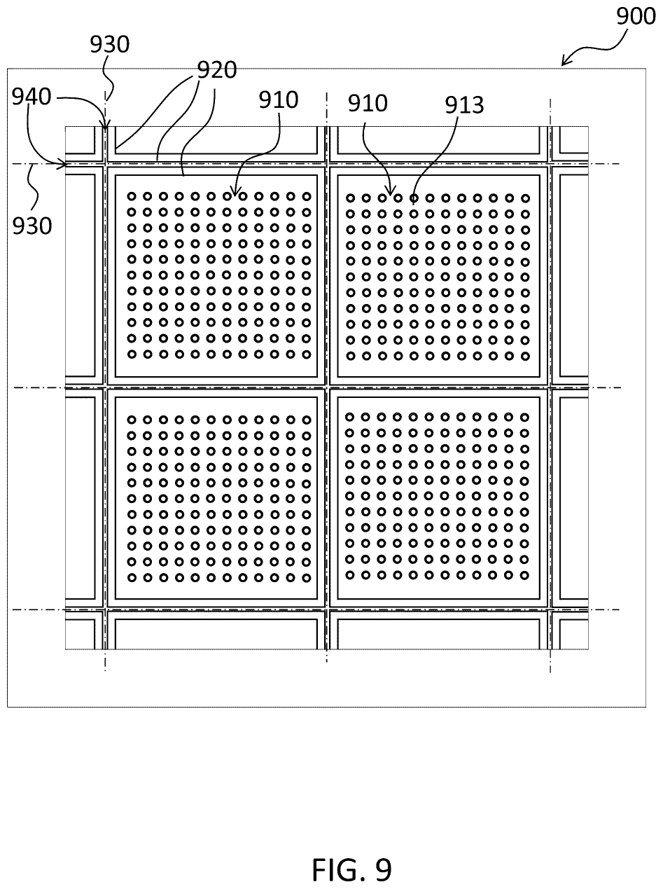

FIG. 9 illustrates a bonding surface 900 according to an example. The bonding surface 900 includes a plurality of chip regions 910. Each of the chip regions 910 includes a transmission metal region 912. A wafer including the bonding surface 900 is cut by dicing along a boundary line 930 defined in a grid shape on the bonding surface 900 at the boundary of the chip regions. The bonding surface 900 illustrated in FIG. 9 includes a peripheral metal region 930 formed along the boundary line 930 and a non-metal region 940 formed so as to pass through the center of a bonding metal region 930 and include the boundary line 930. The boundary line 930 is defined inside or along this non-metal 940. Alternatively, conversely, the boundary line 930 is defined along the non-metal part 940. Therefore, the wafer is cut along the non-metal 940 of this peripheral metal region 920 and divided into a plurality of chip regions 910. In FIG. 9, the peripheral metal region 920 is connected to the ground and functions as a ground metal region.

The cut metal region 820 and the peripheral metal region 920 are not limited to the aspects illustrated in FIGS. 8 and 9, and, for example, may be connected to or configured to be connected to the ground, or need not be connected to the ground. When a wafer having such the bonding surface 800 or 900 is bonded to a substrate such as another wafer, the cut metal region 820 and the peripheral metal region 920 also contribute to the bonding. This can improve, for example, non-restrictively, the bonding strength, and/or can improve the signal transmission characteristics.

All or some of features of the examples illustrated in FIGS. 6 to 9 are not limited to the illustrated examples, and may be used in combination with one another or may be incorporated into another embodiment as long as there is no contradiction.

### <2. Bonding Method>

First, a bonding method according to an embodiment will be described.

At least a pair of substrates is provided. In some embodiments, both of the pair of substrates include a ground metal region (or a power supply metal region) and a signal transmission metal region.

Next, a corresponding metal region is brought into contact with a corresponding region of the other substrate.

An electrical connection is formed between predetermined metal regions.

In other embodiments, one substrate need not necessarily include metal regions corresponding to all metal regions of the other substrate. For example, at least one substrate may include a ground metal region (or a power supply metal region) and a signal transmission metal region, and the other substrate may include at least one of them. One substrate need not necessarily include metal regions corresponding to all metal regions of the other substrate. Between the two connected substrates, the two substrates are bonded so as to enable necessary signal transmission.

The surface of the metal region may be activated before brought into contact with the substrate. This can improve the bonding strength, for example. Alternatively, sufficient strength can be obtained at a low temperature. Furthermore, even when heating is performed after contact, thermal energy thereof can be suppressed.

### <Room Temperature Bonding Method by Surface Activation>

A surface activation treatment may include irradiating a surface of a metal region, a metal (usually covered with an oxide in the atmosphere) such as a metal material, a non-metal region, an insulating material, or the like with energy or energy particles.

The energy particles may be generated by accelerating gas particles to be used, ions of atoms, neutral atoms, or a mixed gas thereof using a particle beam source such as an ion beam source or a fast atom beam (FAB) source. Irradiation of the energy particles may be performed using a plasma source.

In some embodiments, it is possible to give the particles a predetermined kinetic energy by using a particle beam source. The particle beam source is operated in a vacuum, for example with a pressure of equal to or less than 1×10⁻⁵ Pascal (Pa). By the operation of a vacuum pump in order to draw a relatively high vacuum, a substance removed from the surface of the metal region is efficiently exhausted to the outside of the atmosphere. This makes it possible to suppress adhesion of an undesirable substance to an exposed newborn surface. Furthermore, the particle beam source can apply a relatively high acceleration voltage, and thus a high kinetic energy can be imparted to the particles. Therefore, it is considered that removal of a surface layer and activation of the newborn surface can be efficiently performed.

As a neutral atom beam source, a fast atom beam source (FAB) can be used. The fast atom beam source (FAB) typically has a configuration of generating plasma of gas, applying an electric field to this plasma, extracting cations of particles ionized from the plasma, and passing the cations through an electron cloud to be neutralized. In this case, for example, in a case of argon (Ar) as a rare gas, the supply power to the fast atom beam source (FAB) may be set to 1.5 kilovolts (kV), 15 milliamperes (mA), or may be set to a value between 0.1 and 500 watts (W). For example, when a fast atom beam source (FAB) is operated at 100 watts (W) to 200 watts (W) and irradiating with a fast atom beam of argon (Ar) for about 2 minutes, the oxide, contaminants, and the like (surface layer) on the surface to be bonded are removed, and a newborn surface can be exposed.

As the ion beam source, a cold cathode type ion source can be used.

The energy particles may be or may include a rare gas. The rare gas may be argon or another rare gas. The energy particles may be neutral atoms or ions, may be a radical species, or may be a particle group in which these are mixed.

In some embodiments, the surface activation treatment may include irradiating with an electromagnetic wave such as an ultraviolet ray or a laser.

The “surface activation” means a treatment or a process performed on a surface on which substantial binding or bonding is not performed when the surface is brought into contact without this, and means a treatment or the like in which desired or substantially effective binding is obtained when the surfaces after the treatment or the like are brought into contact with each other. A laminated body formed by bonding the substrates after the surface activation treatment may be subjected to or need not be subjected to heating or light treatment as it is.

The removal rate of the surface layer can change according to the operating conditions of each plasma or beam source, the kinetic energy of particles, or irradiation of an electromagnetic wave. Therefore, it is necessary to adjust each condition including the treatment time of the surface activation treatment. For example, using a surface analysis method such as Auger electron spectroscopy (AES) or X-ray photo electron spectroscopy (XPS), a time during which the presence of oxygen or carbon contained in the surface layer can no longer be confirmed or a longer time may be employed as the treatment time of the surface activation treatment.

Surface activation may refer to a treatment or a process performed after thin film formation or on a substrate in some embodiments, and need not be so in some embodiments. In some embodiments, surface activation may mean or include keeping a bonding surface of a thin film active from formation of the thin film. For example, surface activation may include forming a thin film in a vacuum and bonding the substrate without breaking the vacuum. An active surface may be formed in a vacuum and the substrates may be stuck as it remains active.

A surface on which a thin film material is formed may be subjected to surface activation before the thin film is formed. This can exemplarily increase the bonding strength between the substrate and the thin film.

Bonding or sticking the substrates may include bringing the bonding surfaces of the substrates into contact with each other. In some embodiments, bonding or sticking the substrates may include bringing the bonding surfaces of the substrates having been subjected to surface activation with each other.

In some embodiments, a force or pressure may be applied to the substrate from a side opposite to the bonding surface of the substrate or from a surface other than the bonding surface when brought into contact. Pressurization can increase the degree of adhesion at the bonding interface, for example.

In some embodiments, a force or pressure may be applied to the bonding surface or the bonding interface. For example, a force in a perpendicular direction to the bonding surface may be applied from the outside of the substrate. In some embodiments, the substrate may be pressure-welded or pressure-bonded during substrate bonding. In some embodiments, pressurization may be application of a force so as to become substantially even over the entire bonding surface having come into contact. In some embodiments, pressurization may be performed at respective timings on different surfaces of the bonding surface having come into contact. The strength of the force upon pressurization may be temporally constant or variable. Pressurization may be performed at different timings for each site of the bonding surface. The bonding surface may be sequentially pressurized by sliding and moving a pressurization device with respect to the substrate having come into contact. The pressurization device may include a roller-shaped pressurization unit.

In the bonding method for a substrate included in the present disclosure, from surface activation for the bonding surface or the thin film on the bonding surface to contact of the substrate, and from formation, on the bonding surface, of an oxide layer of a metal on the substrate to contact or sticking of the pair of substrates may be performed consistently in vacuum or in an atmosphere under low pressure, or may be performed without breaking the vacuum or the low pressure atmosphere. The atmosphere in vacuum or under low pressure may be an atmosphere having a gas pressure of 10⁻¹⁶ Pa or less. Alternatively, during that time, the substrate may be taken out once from the vacuum after the surface activation, but at that time, the bonding surface is avoided from being exposed to the atmosphere by temporarily bonding a dummy substrate to the bonding surface, and after being returned to the vacuum again, the dummy substrate may be removed to bring the bonding surfaces into contact with each other in the vacuum. The atmosphere in vacuum or under low pressure may include this. By performing these processes in the vacuum, it is possible to avoid adhesion and adsorption of an unnecessary substance to the bonding surface, or oxidation and hydroxylation of the bonding surface, efficiently perform surface activation, maintain the activity of the activated surface or suppress a decrease in it as much as possible, and avoid or reduce generation of a part that is not bonded.

In some embodiments, the stuck substrates (in the present disclosure, also called a bonded body, a substrate laminated body, or the like) may be subjected to heat treatment. In some embodiments, the bonded body may be subjected to heat treatment. In some embodiments, the entire bonded body may be heated. In some embodiments, a reaction may be caused by irradiating the bonded body with light such as a laser or an electromagnetic wave.

In some embodiments, heat treatment may be performed in an inert atmosphere. The inert atmosphere may be a vacuum, a nitrogen atmosphere, or a rare gas atmosphere such as argon or helium. Oxidation of the thin film material and the material inside the substrate by the heat treatment can be reduced or avoided. In some embodiments, heat treatment may be performed in an active atmosphere. For example, heat treatment may be performed in ozone.

In some embodiments, the substrate may be pressurized or pressure-bonded during heat treatment.

The bonding strength of the bonded body may be equal to or greater than a value such as 2 J/m², 3 J/m², or 4 J/m² or larger than that. The bonding strength may be higher than a breaking strength of at least one of the pair of substrates.

In some embodiments, the surface of the metal region may be activated and bonded, and the insulating surface need not be bonded. In some embodiments, the surface of the metal region may be activated and bonded, and the insulating surface may be bonded. The surface of the insulating surface may also be activated.

### <Bonding by Heating>

In some embodiments, surface activation need not be performed. For example, the substrates may be brought into contact with each other, and both of the substrates may be heated in a contact state. By heating, an oxide, an impurity, and the like present on the surface of the metal region are removed, and the metal is brought into direct contact with another metal, whereby a strong bonding can be formed. Even if the surface is activated, heat may be applied after contact or bonding.

### <Low-Temperature Bonding Method>

For example, as illustrated in FIG. 2, at the time of bonding, an insulator may come into contact with an insulator or a metal region of another substrate. In some embodiments, the insulator may come into contact with the metal region simultaneously. For example, as illustrated in FIG. 1, a substrate in which the metal region is formed to protrude from an insulating surface may be used. Even when a part of the metal region comes into contact with another substrate, electrically and/or mechanically sufficient bonding is not formed. However, a part of the insulator may come into contact with and bonded to another substrate. When the insulator has a high surface activity, bonding of the insulator occurs first, and the bonding area increases. Due to this, pressure is applied to the surface of the protruding metal region, and the metal region is compressed. This makes it possible to give firm bonding of the metal region. In some embodiments, the insulator may come into contact with another substrate first, and substantially subsequently the metal region may come into contact or be bonded. In some embodiments, the insulator may come into contact with another substrate first, and substantially subsequently the metal region may come into contact or be bonded.

The surface of the insulating surface may be, for example, a fluorinated oxide, a compound containing Si-O-F, or the like. Fluorination treatment may be performed by exposure to a fluorine-containing liquid, vapor, or gas, or introduction by ion implantation. The surface may be further terminated with NH₂ groups. The surface may expose, for example, the bonding surface to NH₄OH solution. In these treatments, the insulating surface, for example, the surface of an oxide can obtain a high binding force at a relatively low temperature (room temperature or the like).

### <3. Signal Transmission Characteristics>

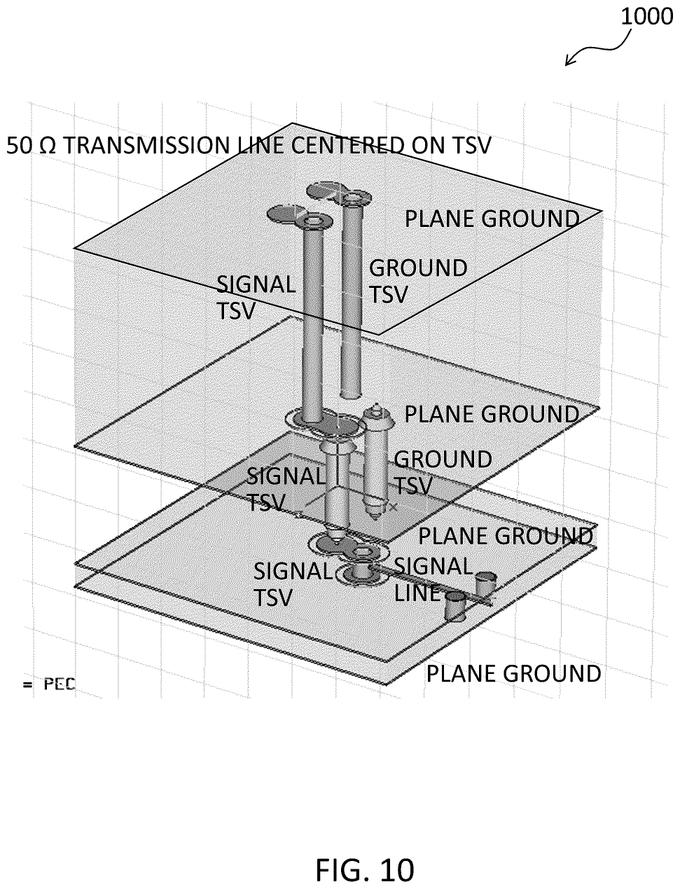

FIG. 10 illustrates the structure of a substrate bonded body 1000 used in simulation. The substrate bonded body 1000 includes three layers, and in those layers, plane grounds (ground metal regions) and signal transmission pads are disposed on an upper surface and a lower surface. A ground TSV and a signal TSV connect between the layers. The present model is configured to have a transmission line of 50 Ω.

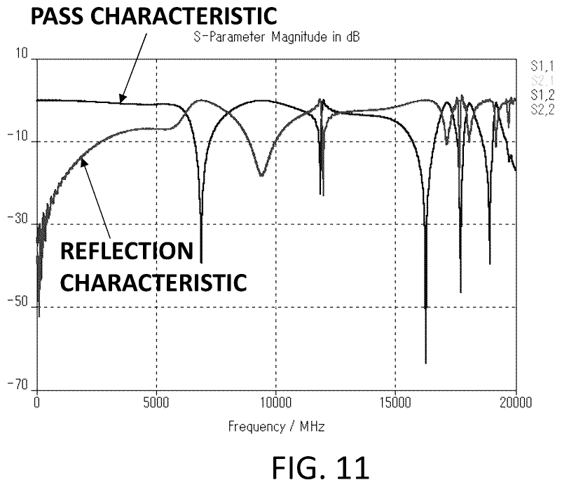

FIG. 11 illustrates a pass characteristic and a reflection characteristic of a signal performed for the model shown in FIG. 10. The horizontal axis represents a signal frequency (Megahertz, MHz), and the vertical axis represents a signal intensity (decibel, dB). A resonance considered to be due to mismatch of pad impedance is seen. That is, the signal is repeatedly reflected between the pads via the TSV, whereby the pass characteristic is attenuated, the reflection characteristic is increased, and the frequency thereof is sharply disturbed. The frequency of primary reflection is determined by the length of each TSV. The frequency close to 20 GHz is considered to be the frequency of a secondary resonance mode. It is possible to reduce these resonances. For example, the thickness of the substrate may be thinned, and the length of the TSV may be reduced. This can shift the resonance frequency corresponding to the length of the TSV in a higher direction. From this result, a good pass characteristic can be obtained up to a high frequency (e.g., about 20 GHz).

The present disclosure also provides the following embodiments:

### A001

A bonding structure including:
a first substrate including a first bonding surface including a first signal transmission metal region and a first ground metal region insulated from the first signal transmission metal region; and
a second substrate bonded to the first substrate, the second substrate including a second bonding surface including a second signal transmission metal region and a second ground metal region insulated from the second signal transmission metal region, in which
the first signal transmission metal region and the second signal transmission metal region are bonded, and
the first ground metal region and the second ground metal region are bonded.

### A002

The bonding structure according to any of the above embodiments, in which
the first substrate includes a through electrode penetrating the first substrate and connected to the first signal transmission metal region, and/or
the second substrate includes a through electrode penetrating the second substrate and connected to the second signal transmission metal region.

### A003

The bonding structure according to any of the above embodiments, in which
the first substrate includes a through electrode penetrating the first substrate and connected to the first ground metal region, and/or
the second substrate includes a through electrode penetrating the second substrate and connected to the second ground metal region.

### A004

The bonding structure according to any of the above embodiments, in which
the first and/or second ground metal region is connected to a ground or a power supply.

### A005

The bonding structure according to any of the above embodiments, in which
the first signal transmission metal surface and/or the first signal transmission metal surface is connected to an electronic element (e.g., a transistor), and
the ground or the power supply is a ground or a power supply of the electronic element (e.g., a transistor).

### A011

The bonding structure according to any of the above embodiments, in which
a total area of the first signal transmission metal region and the first ground metal region is equal to or greater than 10% of an area of the first bonding surface, and/or
a total area of the second signal transmission metal region and the second ground metal region is equal to or greater than 10% of an area of the second bonding surface.

### A012

The bonding structure according to any of the above embodiments, in which
a total area of the first signal transmission metal region and the first ground metal region is equal to or greater than 30% of an area of the first bonding surface, and/or
a total area of the second signal transmission metal region and the second ground metal region is equal to or greater than 30% of an area of the second bonding surface.

### A013

The bonding structure according to any of the above embodiments, in which
a total area of the first signal transmission metal region and the first ground metal region is equal to or greater than 60% of an area of the first bonding surface, and/or
a total area of the second signal transmission metal region and the second ground metal region is equal to or greater than 60% of an area of the second bonding surface.

### A014

The bonding structure according to any of the above embodiments, in which
an area of the first or second ground metal region is larger than an area of the first or second signal transmission metal region.

### A021

The bonding structure according to any of the above embodiments, in which
the first or second signal transmission metal region is substantially surrounded by the first or second ground metal region in the first or second bonding surface.

### A031

The bonding structure according to any of the above embodiments, in which
the first or second signal transmission metal region is disposed separately from the first or second ground metal region in the first or second bonding surface.

### A033

The bonding structure according to any of the above embodiments, in which
the first or second signal transmission metal region is disposed separately by equal to or greater than 0.1 μm from the first or second ground metal region in the in-plane direction of the first or second bonding surface.

### A034

The bonding structure according to any of the above embodiments, in which
the first or second bonding surface includes an insulating surface at a separation part between the first or second signal transmission metal region and the first or second ground metal region.

### A035

The bonding structure according to any of the above embodiments, in which
the first bonding surface includes a first insulating surface disposed between the first signal transmission metal region and the first ground metal region,
the second bonding surface includes a second insulating surface disposed between the second signal transmission metal region and the second ground metal region, and
the first insulating surface and the second insulating surface are bonded to each other.

### A035b

The bonding structure according to any of the above embodiments, in which
the first bonding surface includes a first insulating surface disposed between the first signal transmission metal region and the first ground metal region,
the second bonding surface includes a second insulating surface disposed between the second signal transmission metal region and the second ground metal region, and
the first insulating surface and the second insulating surface are not bonded to each other.

### A036

The bonding structure according to any of the above embodiments, in which
the first or second signal transmission metal region and the first or second ground metal region are not in contact with each other.

### A037

The bonding structure according to any of the above embodiments, in which
a separation part between the first or second signal transmission metal region and the first or second ground metal region is formed of gas or substantial vacuum.

### A041

The bonding structure according to any of the above embodiments, in which
the first and/or second signal transmission metal region includes a plurality of first and/or second signal transmission metal regions.

### A042

The bonding structure according to any of the above embodiments, in which
the plurality of first and/or second signal transmission metal regions include at least one signal transmission metal region for transmitting an analog signal and at least one signal transmission metal region for transmitting a digital signal.

### A051

The bonding structure according to any of the above embodiments, in which
the first and/or second ground metal region includes a plurality of first and/or second ground metal regions insulated from each other in a corresponding bonding surface.

### A052

The bonding structure according to any of the above embodiments, in which
the plurality of first and/or second ground metal regions are connected to a ground and/or different power supplies.

### A053

The bonding structure according to any of the above embodiments, in which
a part of the plurality of first and/or second ground metal regions is disposed to surround the signal transmission metal region for an analog signal in a corresponding bonding surface, and
another part of the plurality of first and/or second ground metal regions is disposed to surround the signal transmission metal region for a digital signal in a corresponding bonding surface.

### A061

The bonding structure according to any of the above embodiments, in which
the ground metal region has a metal material disposed in the entire region or gaplessly.

### A062

The bonding structure according to any of the above embodiments, in which
the ground metal region has a metal material disposed so as to cover a part of a region thereof in terms of area.

### A063

The bonding structure according to any of the above embodiments, in which
the ground metal region has a metal material non-occupancy part in which no metal material is disposed.

### A064

The bonding structure according to any of the above embodiments, in which
the metal material non-occupancy part is periodically disposed in the entirety or a part of the ground metal region.

### A065

The bonding structure according to any of the above embodiments, in which
the metal material non-occupancy part or the metal material is periodically disposed in the ground metal region,
periodically disposed in the entirety or a part of the ground metal region.

### A066

The bonding structure according to any of the above embodiments, in which
the metal material non-occupancy part or the metal material is disposed in a mesh shape in the ground metal region.

### A067

The bonding structure according to any of the above embodiments, in which
an area of the metal material non-occupancy part is 10% to 50% of an area of the ground metal region.

### A101

A bonding structure including:
a first substrate including a first bonding surface including a first signal transmission metal region and a first ground metal region insulated from the first signal transmission metal region;
a second substrate bonded to the first substrate, the second substrate including
a second upper bonding surface including a second upper signal transmission metal region and a second upper ground metal region insulated from the second upper signal transmission metal region, the second upper bonding surface facing the first bonding surface, and
a second lower bonding surface including a second lower signal transmission metal region and a second lower ground metal region insulated from the second lower signal transmission metal region; and
a third substrate bonded to the second substrate, the third substrate including a third bonding surface including a third signal transmission metal region and a third ground metal region insulated from the third signal transmission metal region, the third bonding surface facing the second lower bonding surface, in which
the first signal transmission metal region and the second upper signal transmission metal region are bonded,
the first ground metal region and the second upper ground metal region are bonded,
the second lower signal transmission metal region and the third signal transmission metal region are bonded, and
the second lower ground metal region and the third ground metal region are bonded.

### A102

The bonding structure according to any of the above embodiments including:
a plurality of substrates bonded to each other.

### A201

An electronic element including the bonding structure according to any of the above embodiments.

### A202

An electronic circuit module including the bonding structure according to any of the above embodiments.

### A203

An electronic device including the bonding structure according to any of the above embodiments.

### B001

A method of bonding a substrate, the method including:
providing a first substrate including a first bonding surface including a first signal transmission metal region and a first ground metal region insulated from the first signal transmission metal region;
providing a second substrate bonded to the first substrate, the second substrate including a second bonding surface including a second signal transmission metal region and a second ground metal region insulated from the second signal transmission metal region;
bringing the first signal transmission metal region and the second signal transmission metal region into contact with each other; and
bringing the first ground metal region and the second ground metal region into contact with each other.

### B011

The method according to any of the above embodiments, in which
bringing the first signal transmission metal region and the second signal transmission metal region into contact with each other includes electrically connecting the first signal transmission metal region and the second signal transmission metal region with each other, and
bringing the first ground metal region and the second ground metal region into contact with each other includes electrically connecting the first ground metal region and the second ground metal region with each other.

### B012

The method according to any of the above embodiments further including:
before bringing the first signal transmission metal region and the second signal transmission metal region into contact with each other and bringing the first ground metal region and the second ground metal region into contact with each other,
activating a surface of at least one of the first signal transmission metal region and the second signal transmission metal region, and
activating a surface of at least one of the first ground metal region and the second ground metal region, in which
bringing the first signal transmission metal region and the second signal transmission metal region into contact with each other includes bringing the activated surface into contact with an other, and
bringing the first ground metal region and the second ground metal region into contact with each other includes bringing the activated surface into contact with an other.

### B013

The method according to any of the above embodiments, in which
the bringing into contact with each other includes bringing into contact with each other in a vacuum.

### B014

The method according to any of the above embodiments, in which
the activation includes a process selected from the group consisting of plasma treatment, ion bombardment, atom beam irradiation, radical irradiation, and electromagnetic wave irradiation.

### B015

The method according to any of the above embodiments, in which
bringing the first signal transmission metal region and the second signal transmission metal region into contact with each other and bringing the first ground metal region and the second ground metal region into contact with each other are performed in an unheated manner or at room temperature.

### B016

The method according to any of the above embodiments further including:
after bringing the first signal transmission metal region and the second signal transmission metal region into contact with each other; and
bringing the first ground metal region and the second ground metal region into contact with each other, heating the first substrate and the second substrate.

Terms or expressions indicating the positional relationship such as “upper substrate”, “intermediate substrate”, “lower substrate”, “second layer from the top”, “upper surface”, “lower surface”, “upper side”, “lower side”, and the like used in the present description are not necessarily construed as being determined with respect to a vertical direction, a gravity direction, or a specific direction of a device, but are used exemplarily or for convenience in describing the drawings. For example, “upper substrate”, “intermediate substrate”, and “lower substrate” may be respectively expressed as “first substrate”, “second substrate”, and “third substrate” (the order is arbitrary) , and “upper surface” and “lower surface” may be respectively expressed as “first substrate” and “second substrate” (the order is arbitrary), or may be expressed by appropriately using arbitrary numbers, adjectives, other nouns, or combinations thereof.

Some embodiments and examples of the present disclosure have been described above, and these embodiments and examples exemplarily describe the present disclosure. For example, each of the above embodiments has been described in detail in order to describe the present disclosure in an easy-to-understand manner, and dimensions, configurations, materials, and circuits may be additionally changed as necessary. Note that embodiments in which one or a plurality of features of the present disclosure described above are arbitrarily combined are also included in the scope of the present disclosure. The claims include many modifications to the embodiments in a scope not departing from the technical idea of the present disclosure. Therefore, the embodiments and examples disclosed in the present description are presented by way of illustration and are not to be considered as restrictive of the scope of the present disclosure.

1. A bonding structure comprising:
a first substrate including a first bonding surface including a first signal transmission metal region and a first ground metal region insulated from the first signal transmission metal region; and
a second substrate bonded to the first substrate, the second substrate including a second bonding surface including a second signal transmission metal region and a second ground metal region insulated from the second signal transmission metal region, wherein
the first signal transmission metal region and the second signal transmission metal region are bonded,
the first ground metal region and the second ground metal region are bonded, and
the first or second signal transmission metal region is substantially surrounded by the first or second ground metal region in the first or second bonding surface.

2. The bonding structure according to claim 1, wherein
a total area of the first signal transmission metal region and the first ground metal region is equal to or greater than 50% of an area of the first bonding surface, and/or
a total area of the second signal transmission metal region and the second ground metal region is equal to or greater than 50% of an area of the second bonding surface.

3. The bonding structure according to claim 1, wherein an area of the first or second ground metal region is larger than an area of the first or second signal transmission metal region.

4. The bonding structure according to claim 1, wherein an insulating surface of the first bonding surface and an insulating surface of the second bonding surface are not bonded to each other.

5. The bonding structure according to claim 1, wherein
the first signal transmission metal region and the second signal transmission metal region being bonded is a plurality of first signal transmission metal pins disposed in the first signal transmission metal region and a plurality of second signal transmission metal pins disposed in the second signal transmission metal region being bonded, and
the first ground metal region and the second ground metal region being bonded is a plurality of first ground metal pins disposed in the first ground metal region and a plurality of second ground metal pins disposed in the second ground metal region being bonded.

6. The bonding structure according to claim 1, wherein
the first substrate and the second substrate are chips cut from a wafer by dicing, and
the first and second ground metal regions are ground metal regions formed by cutting the wafer along a boundary line in a cut metal region.

7. The bonding structure according to claim 1, wherein
the first substrate and the second substrate are chips cut from a wafer by dicing,
a plurality of chip regions are defined on the wafer, a ground metal region is formed at a boundary of each of the plurality of chip regions, a non-metal region is formed at boundary lines of the plurality of chip regions, and
the chips are formed by dicing along the non-metal regions.

8. The bonding structure according to claim 1, wherein
the first substrate includes a through electrode penetrating the first substrate and connected to the first signal transmission metal region, and/or
the second substrate includes a through electrode penetrating the second substrate and connected to the second signal transmission metal region.

9. The bonding structure according to claim 1, wherein
the first substrate includes a through electrode penetrating the first substrate and connected to the first ground metal region, and/or
the second substrate includes a through electrode penetrating the second substrate and connected to the second ground metal region.

10. The bonding structure according to claim 1, wherein the first or second signal transmission metal region is disposed separately from the first or second ground metal region in the first or second bonding surface.

11. The bonding structure according to claim 10, wherein the first or second bonding surface includes an insulating surface at a separation portion between the first or second signal transmission metal region and the first or second ground metal region.

12. The bonding structure according to claim 10, wherein
the first bonding surface includes a first insulating surface disposed between the first signal transmission metal region and the first ground metal region,
the second bonding surface includes a second insulating surface disposed between the second signal transmission metal region and the second ground metal region, and
the first insulating surface and the second insulating surface are bonded to each other.

13. The bonding structure according to claim 10, wherein
the first bonding surface includes a first insulating surface disposed between the first signal transmission metal region and the first ground metal region,
the second bonding surface includes a second insulating surface disposed between the second signal transmission metal region and the second ground metal region, and
the first insulating surface and the second insulating surface are not bonded to each other.

14. The bonding structure according to claim 1, wherein the first and/or second signal transmission metal region includes a plurality of first and/or second signal transmission metal regions, and
the plurality of first and/or second signal transmission metal regions are surrounded by a single first and/or second ground metal region.

15. The bonding structure according to claim 1, wherein the first and/or second signal transmission metal region includes a plurality of first and/or second signal transmission metal regions, and
the plurality of first and/or second signal transmission metal regions include at least one signal transmission metal region for transmitting an analog signal and at least one signal transmission metal region for transmitting a digital signal.

16. The bonding structure according to claim 1, wherein the first and/or second ground metal region includes a plurality of first and/or second ground metal regions insulated from each other in a corresponding bonding surface.

17. The bonding structure according to claim 16, wherein the plurality of first and/or second ground metal regions are connected to a ground and/or different power supplies.

18. The bonding structure according to claim 1, wherein
the first and/or second signal transmission metal region includes a plurality of first and/or second signal transmission metal regions,
a part of the plurality of first and/or second ground metal regions is disposed to surround the signal transmission metal region for an analog signal in a corresponding bonding surface, and
another part of the plurality of first and/or second ground metal regions is disposed to surround the signal transmission metal region for a digital signal in a corresponding bonding surface.

19. A bonding structure comprising:
a first substrate including a first bonding surface including a first signal transmission metal region and a first ground metal region insulated from the first signal transmission metal region;
a second substrate bonded to the first substrate, the second substrate including
a second upper bonding surface including a second upper signal transmission metal region and a second upper ground metal region insulated from the second upper signal transmission metal region, the second upper bonding surface facing the first bonding surface, and
a second lower bonding surface including a second lower signal transmission metal region and a second lower ground metal region insulated from the second lower signal transmission metal region; and
a third substrate bonded to the second substrate, the third substrate including a third bonding surface including a third signal transmission metal region and a third ground metal region insulated from the third signal transmission metal region, the third bonding surface facing the second lower bonding surface, wherein
the first signal transmission metal region and the second upper signal transmission metal region are bonded,
the first ground metal region and the second upper ground metal region are bonded,
the second lower signal transmission metal region and the third signal transmission metal region are bonded,
the second lower ground metal region and the third ground metal region are bonded,
the first or second upper signal transmission metal region is substantially surrounded by the first or second upper ground metal region in the first or second upper bonding surface, and
the second lower or third signal transmission metal region is substantially surrounded by the second lower or third ground metal region in the second lower or third bonding surface.

20. The bonding structure according to claim 1, further comprising a plurality of substrates bonded to each other.

21. An electronic element, an electronic circuit module, or an electronic device comprising the bonding structure according to claim 1.

22. A method of bonding a substrate, the method comprising:
providing a first substrate including a first bonding surface including a first signal transmission metal region and a first ground metal region insulated from the first signal transmission metal region;
providing a second substrate bonded to the first substrate, the second substrate including a second bonding surface including a second signal transmission metal region and a second ground metal region insulated from the second signal transmission metal region;
electrically connecting the first signal transmission metal region and the second signal transmission metal region; and
electrically connecting the first ground metal region and the second ground metal region,
wherein the first or second signal transmission metal region is substantially surrounded by the first or second ground metal region in the first or second bonding surface.

23. The method according to claim 22 further comprising:
before electrically connecting the first signal transmission metal region and the second signal transmission metal region and electrically connecting the first ground metal region and the second ground metal region,
activating a surface of at least one of the first signal transmission metal region and the second signal transmission metal region; and
activating a surface of at least one of the first ground metal region and the second ground metal region, wherein
said electrically connecting the first signal transmission metal region and the second signal transmission metal region includes bringing the activated surface into contact with another, and
said electrically connecting the first ground metal region and the second ground metal region includes bringing the activated surface into contact with another.

24. The method according to claim 23, wherein said bringing into contact with another includes bringing into contact with another in a vacuum.

25. The method according to claim 23, wherein the activation includes a process selected from the group consisting of plasma treatment, ion bombardment, atom beam irradiation, radical irradiation, and electromagnetic wave irradiation.

26. The method according to claim 22, wherein said electrically connecting the first signal transmission metal region and the second signal transmission metal region and said electrically connecting the first ground metal region and the second ground metal region are performed in an unheated manner or at room temperature.

27. The method according to claim 22, further comprising after electrically connecting the first signal transmission metal region and the second signal transmission metal region and electrically connecting the first ground metal region and the second ground metal region, heating the first substrate and the second substrate.

28. The method according to claim 22, wherein
said electrically connecting the first signal transmission metal region and the second signal transmission metal region; and said electrically connecting the first ground metal region and the second ground metal region comprise:
activating surfaces of the first signal transmission region, the second signal transmission metal region, the first ground metal region and the second ground metal region by irradiation of a particle beam under a vacuum of equal to or less than 1×⁻⁵ Pascal (Pa); and
bonding the first signal transmission metal region and the second signal transmission metal region and bonding the first ground metal region and the second ground metal region, as they remain active.

29. (canceled)
